(19) United States
(12) Patent Application Publication
(10) Pub. No.: US 2016/0322256 A1
(43) Pub. Date: Nov. 3, 2016

(54) Technique that Patterns Both Sides of a Thin Wafer to Fabricate Bi-Directional Devices

(71) Applicant: Ideal Power Inc., Austin, TX (US)

(72) Inventors: Richard A. Blanchard, Los Altos, CA (US); William C. Alexander, Spicewood, TX (US)

(21) Appl. No.: 15/055,514

(22) Filed: Feb. 26, 2016

Related U.S. Application Data
(60) Provisional application No. 62/121,435, filed on Feb. 26, 2015.

(51) Int. Cl. H01L 21/78; H01L 21/304; H01L 21/683; H01L 21/306

(52) U.S. Cl. CPC H01L 21/78; H01L 21/30604; H01L 21/304; H01L 21/6835; H01L 2221/68327

(57) ABSTRACT

Methods and systems for fabricating bidirectional devices on both surfaces of a semiconductor wafer. Separation of the second handle wafer is accomplished by patterning a seal layer to form a grid before the second handle wafer is separated.

### CROSS-REFERENCE

Priority is claimed from U.S. application 62/121,435, which is hereby incorporated by reference.

### BACKGROUND

The present application relates to two-surface wafer fabrication, and particularly to two-surface wafer fabrication of bidirectional power devices having vertical current flow.

Previous patent applications of the present applicant have disclosed new device structures, new methods of fabrication, and new methods of operation for bipolar power transistors which use the semiconductor bulk as a base region, and which have two separate base contacts on the two surfaces of the device. These patent applications have included, for example, WO2014/210072, WO2015/089227, WO2015/109237, U.S. application Ser. Nos. 14/882,316, 14/918,440, 14/937,814, 14/945,097, and 14/935,344, all of which are hereby incorporated by reference for all purposes.

Fabrication of two-sided devices of this type presents some unique challenges. The wafer will be thinned, and the two sides of the wafer may be required to have approximately identical device structures. Both surfaces of the wafer included patterned doping regions which are sensitive to thermal cycling. This presents challenges. Previous applications, cited above, have disclosed techniques for using two handle wafers to facilitate two-surface processing; the present application discloses additional options and improvements.

The present application teaches techniques for fabrication of bidirectional devices with patterning on both surfaces of a wafer. Several independently useful innovations are disclosed; notably, a “seal” layer is patterned to facilitate separation of the second handle wafer. The actual separation can be performed by etching, or by saw cuts from both sides of the wafer.

### BRIEF DESCRIPTION OF THE DRAWINGS

The disclosed inventions will be described with reference to the accompanying drawings, which show important sample embodiments and which are incorporated in the specification hereof by reference, wherein:

FIGS. 1, 2, 3, 4, 5, 6, 7, 8, and 9 show various processing stages for two classes of sample embodiments according to the present inventions.

FIG. 10 shows a sample detail view corresponding to the sample process phase of FIG. 9.

FIG. 11 shows an exemplary phase of processing that can follow that of FIG. 10.

FIG. 12 shows a complete sample process flow for two classes of sample embodiments.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The process of fabricating bi-directional devices that are patterned on both sides of the wafer requires a technique for protecting the already patterned first side of a wafer when patterning the second side of the wafer. A technique for accomplishing this goal has been described in an earlier patent filing (WO/2015/089227). This previously described technique requires that a first handle wafer be attached to the first side of the device wafer after most of the patterning and associated processing has been completed, but before any processing occurs on the second side of the device wafer. Next, after all of the processing is completed on the second side of the wafer, a second handle wafer is attached to the second side of the device wafer, and the first handle wafer is removed from the first side of the device wafer. The second handle wafer needs to be attached to the second side of the device wafer using a technique that permits subsequent processing at temperatures as high as about 400 C. to complete the fabrication of the first side of the device wafer, but not higher than about 500 C., so that the already completed second side of the device wafer is not damaged by the heat. (Excessive thermal history will increase the diffusion length of dopants, even if metal is not present. If metallization is already present, metal/semiconductor interactions can occur if temperatures are sufficiently high.)

Several techniques might be considered as ways to improve techniques for bonding the second handle wafer to the second side of the device wafer, namely:
1. Wafer-to-wafer bonding at a temperature of 450 C. or lower, using layer(s) of silicon dioxide and/or silicon nitride on the second side of the device wafer: This approach forms an adequate bond, but the subsequent removal of the second handle wafer from the second side of the device wafer is a problem, because of the device wafer thickness at the time this removal step is performed. The device wafer is already at its final thickness, which is typically between 60 microns and 200 microns, and is subject to being broken. The use of a third handle wafer on the first side of the device wafer only changes the side of the device wafer that has a handle wafer that must be removed. One might consider a layer of temporary support on the first side of the device wafer, but a tape that can withstand the required processing steps while providing sufficient strength has not been found.
2. Wafer-to-wafer bonding using an organic adhesion layer: This approach has been investigated, but an organic adhesive that can withstand 400 C. and can be dissolved from between the device wafer and the handle wafer has not been identified. In addition, the problem having to deal with a wafer having a thickness between about 60 um to 200 um is also present.

What is needed is a fabrication flow that allows a second handle wafer to be bonded to the second side of the device wafer, but also allows the second handle wafer to be removed so the completed device wafer can be separated easily and reliably (so that the individual dice can be assembled.

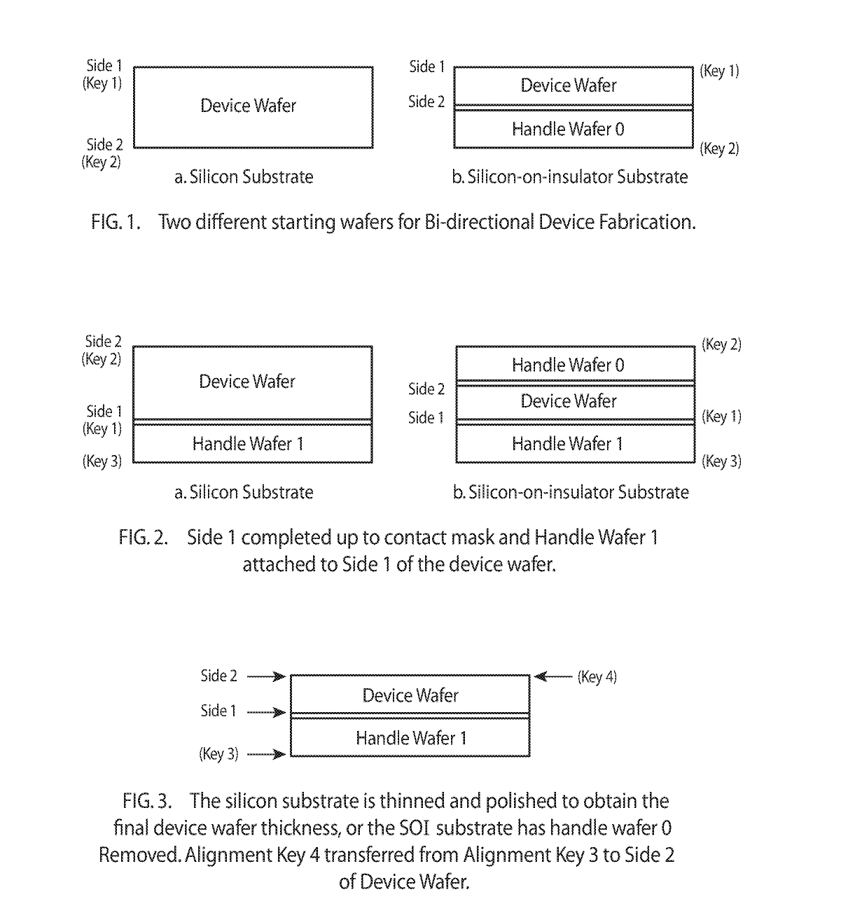

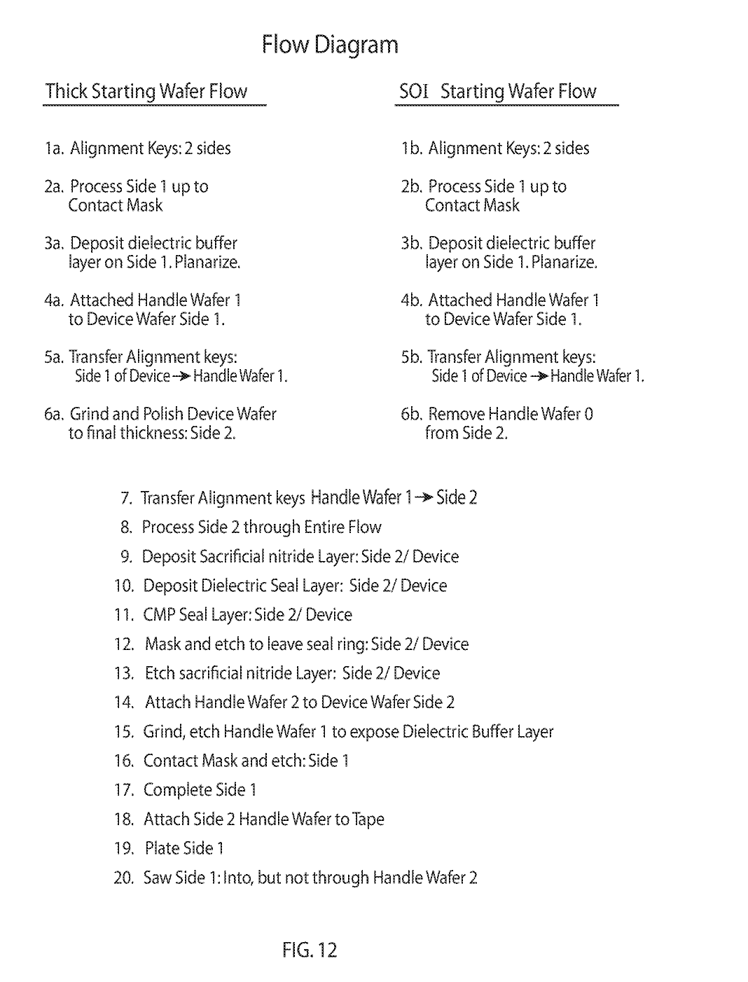

A flow that accomplishes this goal is contained in the process flow diagram of FIG. 12. Cross sections of wafers at specific steps in this flow diagram are shown in FIG. 1-FIG. 9. The exact device structures formed can be as disclosed in the applications referenced above,

FIG. 1 shows two different starting wafers for bidirectional device fabrication. Either starting wafer—monololithic or SOI—can be used in implementing the disclosed inventions.

The monolithic structure has alignment key 1 present on side 1 of the device wafer, and key 2 on side 2. Preferably the wafer is monocrystalline silicon, but silicon carbide or other materials can optionally be used.

The SOI example has an initial handle wafer (“Handle Wafer 0”) already bonded to a thin device wafer. Alignment key 1 is on side 1 of the device wafer, but key 2 is on the back surface of the initial handle wafer.

FIG. 2 shows a further stage of processing, where Side 1 has been completed up to the contact mask, and Handle Wafer 1 has been attached to side 1 of the device wafer. In each case, alignment key 2 is used to define alignment key 3 on the back surface of Handle Wafer 1.

FIG. 3 shows a further stage of processing, where the silicon substrate has been thinned and polished to obtain the final device wafer thickness. (In the SOI case, the SOI substrate has had Handle Wafer 0 removed.) Alignment key 4 is transferred from align key 3 to side 2 of device wafer.

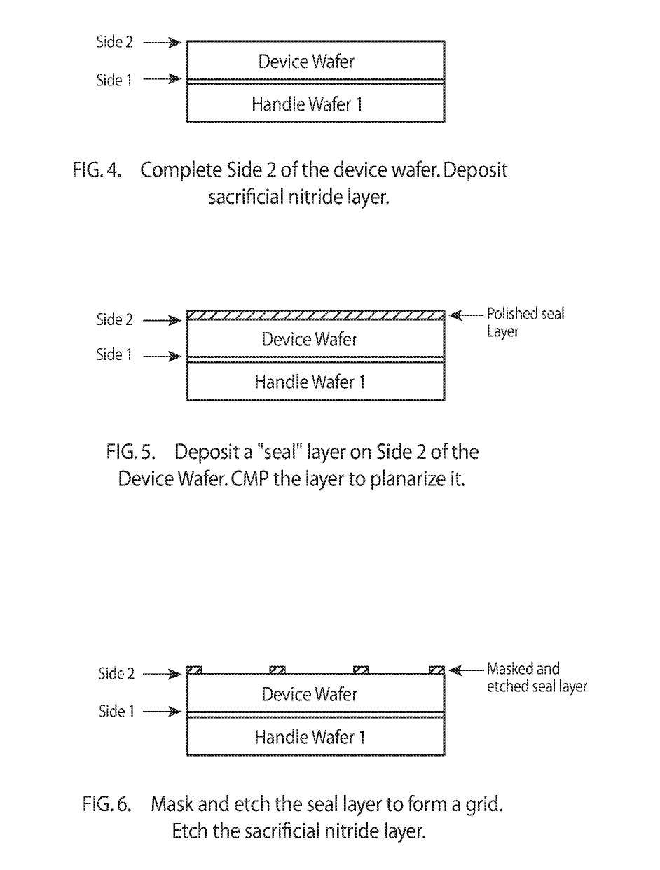

FIG. 4 shows a further stage of processing, where processing of side 2 of the device wafer has been completed, and a sacrificial nitride layer has been deposited.

FIG. 5 shows a further stage of processing, where a “seal” layer has been deposited on side 2 of the device wafer. CMP has been performed on this layer to planarize it.

FIG. 6 shows a further stage of processing, where the seal layer has been masked and etched to form a grid, and the sacrificial nitride layer has been etched accordingly.

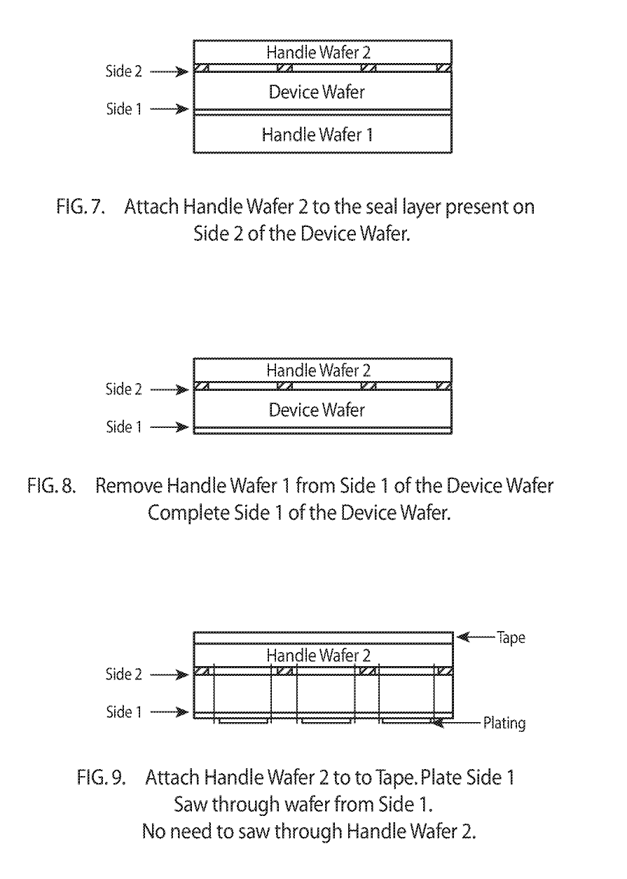

FIG. 7 shows a further stage of processing, where Handle Wafer 2 has been attached to the seal layer present on side 2 of the device wafer.

FIG. 8 shows a further stage of processing, where Handle Wafer 1 has been removed from side 1 of the device wafer, and processing of side 1 of the device wafer has been completed.

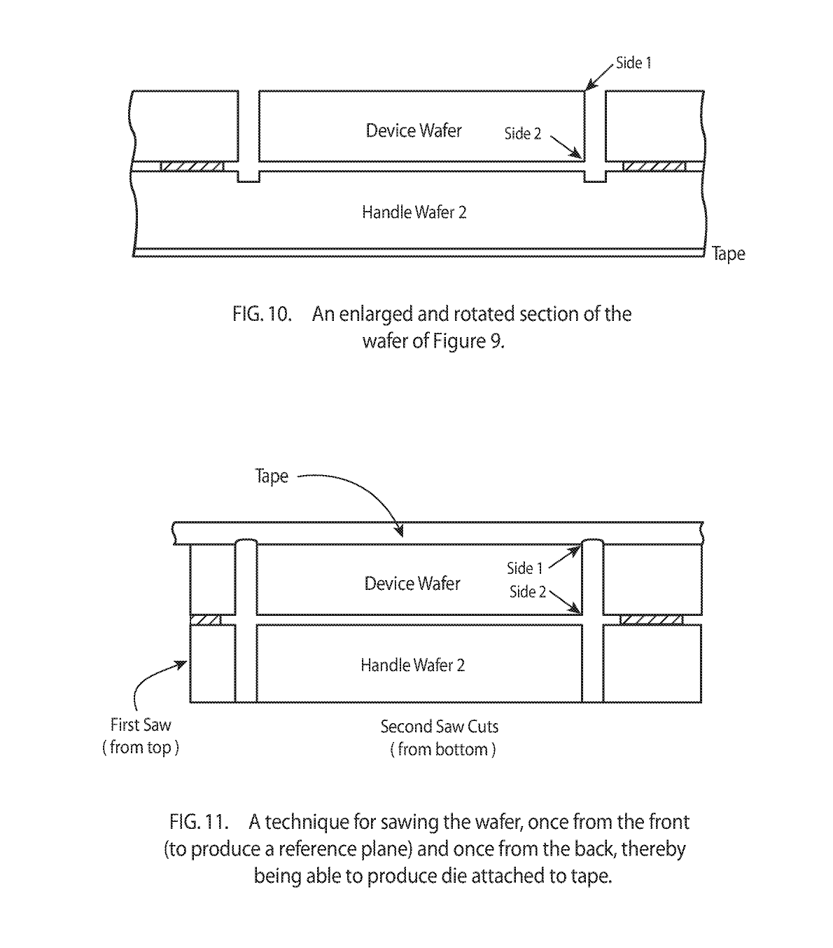

FIG. 9 shows a further stage of processing, where handle wafer 2 has been attached to tape. Side 1 is then plated. The device wafer is then sawn through from side 1. (There is no need to saw through Handle Wafer 2.)

An enlarged region of FIG. 9 is shown in FIG. 10, which shows the cross section of a single die including regions where a saw blade has separated the die from the support wafer.

### Overview of Process Flow

FIG. 12 shows an overview of the innovative process flow. Note that the starting wafer can be monolithic or SOI, and alternatives are indicated accordingly for steps 1a/1b through 6a/6b.
1) Alignment keys: two sides
2) Process side 1 up to contact mask
3) Deposit dielectric buffer layer on side 1. Planarize.
4) Attach Handle Wafer 1 Device Wafer Side 1.
5) Transfer alignment keys: side 1 of device→handle wafer 1
6A) (For thick starting wafer flow) Grind and polish device wafer to final thickness: side 2
6B) (For SOI starting wafer flow) Remove Handle Wafer 0 from side 2
7) Transfer alignment keys Handle Wafer 1→side 2
8) Process side 2 through entire flow
9) Deposit sacrificial nitride layer: device wafer side 2
10) Deposit dielectric seal layer: device wafer side 2
11) CMP seal layer: device wafer side 2
12) Mask and action to leave seal ring: device wafer side 2
13) Etch sacrificial nitride layer: device wafer side 2
14) Attach handle wafer 2 to device wafer side 2
15) Grind, etch handle wafer 1 to expose dielectric buffer layer
16) Contact mask and etch: side 1
17) Complete side 1
18) Attach side 2 handle wafer to tape
19) Plate side 1
20) Saw side 1: into, but not through, handle wafer 2

Process steps that differ from those in earlier process flows will now be discussed in greater detail.

Step 9: The deposition of a relatively thin layer of silicon nitride permits both the subsequent deposition and partial removal a layer of silicon dioxide on the second side of the device wafer and the removal of this sacrificial layer of silicon nitride, exposing the underlying aluminum pads and passivation layer.

Step 10: The dielectric seal layer is similar to the dielectric buffer layer that is deposited at step 3a and 3b. It forms the adhesion layer between the device wafer and the handle wafer.

Step 11: The CMP step provides a planar dielectric seal layer for subsequent wafer-to-wafer bonding.

Step 12: The mask and etch step removes the regions of the dielectric seal layer that are above the device, thereby allowing access to the entire surface of each device across the second side of the device wafer. The remaining regions of the dielectric seal layer forms a grid that surrounds each of the devices.

Step 13: The sacrificial silicon nitride layer is removed using a blanket etch from over each of the devices, exposing the pad and passivation layers.

Step 14: The wafer seal formed between the second side of the device wafer and the second handle wafer occurs only at the top of the grid, leaving the region above each device die covered by the second handle wafer, but not attached to the second handle wafer.

Steps 15-19: These steps are the same as those of the previous process flows.

Step 20: Following the nickel/gold plating step, the wafer has the cross section shown in FIG. 9, but before the wafer saw step. The saw operation cuts through the wafer freeing each device die from the device wafer as shown in FIG. 9.

Another fabrication sequence is generally similar to the one discussed above, but differs in one significant way. Specifically, the steps required to optically transfer the alignment keys from the first side of the device wafer to the second side of the device wafer, thereby allowing front-to-back pattern alignment, are not used. (These steps are one half of Step 1, Step 5, and Step 7.) It has been found difficult to transfer the alignment keys from wafer surface to wafer surface if even a slight amount of wafer bowing or warping occurs. An alignment method that does work in this situation is a mechanical front-to-back alignment technique. While mechanical alignment does not result in the precision of optical surface-to-surface alignment, for a large die, a slight penalty in die area is less than the cost of the processing and the associated yield loss.

The material used to form the grid pattern that attaches the second handle wafer to the second side of the device wafer is a dielectric or a dielectric sandwich in Steps 10-13 of the flow diagram. However, there is no such restriction. Since the bond formed between the second side of the device wafer and the second handle wafer never needs to be removed, other materials, including metals that melt at or below 500 C. or below, metals that form eutectics that melt at 500 C. or below, and organic adhesives that can survive up to 400 C. without the bond failing.

A technique that eliminates the possibility of the device die “floating” after the sawing step, possibly causing damage to the devices, the wafer, or the saw blade is shown in FIG. 11. This figure shows that the saw is used to provide a first set of edges, at least one on the X-axis and one on the Y-axis, that are completely through the bonded wafer using the features on the surface of the first side of the device wafer as a reference. Tape may be present on the bottom of the second handle wafer when these saw cuts are made. Next, tape is placed on the first side of the device wafer, and this surface is placed towards the wafer chuck on the saw. The tape previously on the bottom of the handle wafer is removed, and the straight edges of the wafer are used as references for sawing the wafer completely through with the handle wafer at the top. (Note: Figure shows the final saw cut originating at the bottom of the wafer to be consistent with FIG. 10.) Since the individual dice are attached to the tape during the sawing operation, they are held in place.

One of the advantages of the present innovations, then, is the ability to “blind-saw” free from the back of the wafer, without the need to perform precise front-to-back alignment of the cuts.

Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is, among others (and, without exclusion, in addition to any other points which are indicated herein as inventive and/or surprising and/or advantageous):

1. A method of fabricating bidirectional semiconductor devices having patterned doped regions on both surfaces thereof, comprising the actions of:
a) completing fabrication of patterned doped regions on one surface of a thin semiconductor device wafer which is already attached, at the other surface thereof, to a first handle wafer;
b) forming a sacrificial layer over the patterned doped regions, and a seal layer over the sacrificial layer;
c) patterning and etching the seal to thereby form grid;
d) attaching a second handle wafer to the grid, and removing the first handle wafer from the device wafer; and
e) sawing through the device wafer, in alignment to the grid, to thereby mechanically separate the device wafer from the second handle wafer.

2. A method of fabricating bidirectional semiconductor devices having patterned doped regions on both surfaces thereof, comprising the actions of:
a) completing fabrication of patterned doped regions on one surface of a thin semiconductor device wafer which is already attached, at the other surface thereof, to a first handle wafer;
b) forming a sacrificial silicon nitride layer over the patterned doped regions, and a low-temperature glass layer over the sacrificial layer;
c) patterning and etching the seal layer to form a sparse support lattice;
d) attaching a second handle wafer to the sparse support lattice, and removing the first handle wafer from the device wafer; and
e) sawing through the device wafer, in alignment to the sparse support lattice, to thereby mechanically separate the device wafer from the second handle wafer.

3. A device fabricated by the method of claim 1.

4. A device fabricated by the method of claim 2.
